(19) United States
(12) Patent Application Publication
(10) Pub. No.: US 2024/0274453 A1
(43) Pub. Date: Aug. 15, 2024

(54) SEMICONDUCTOR PRODUCTION SYSTEM AND METHOD

(71) Applicant: Samsung Electronics Co., Ltd., Suwon-si (KR)

(72) Inventors: Minhong YUN, Suwon-si (KR); Shigenobu MAEDA, Suwon-si (KR); Kyungtae KIM, Suwon-si (KR); Donghyun KIM, Suwon-si (KR); Sangyoon PARK, Suwon-si (KR)

(73) Assignee: Samsung Electronics Co., Ltd., Suwon-si (KR)

(21) Appl. No.: 18/440,649

(22) Filed: Feb. 13, 2024

(30) Foreign Application Priority Data
Feb. 14, 2023 (KR) 10-2023-0019630
May 30, 2023 (KR) 10-2023-0069447

(51) Int. Cl. H01L 21/67; G05B 13/02

(52) U.S. Cl. CPC H01L 21/67288; G05B 13/027; H01L 21/67248; H01L 21/67253; H01L 21/67276

(57) ABSTRACT

A semiconductor production system includes: a first chamber that is configured to be set to a first setting value and process wafers; a second chamber that is configured to be set to a second setting value and process the wafers processed in the first chamber; and a fault detection and classification (FDC) modeling module configured to: train a first FDC machine learning model to generate, based on the first setting value and first FDC values sensed with respect to the wafers processed in the first chamber, first predicted FDC values with respect to first virtual wafers in the first chamber; and train a second FDC machine learning model to generate, based on the second setting value and second FDC values sensed with respect to the wafers processed in the second chamber, second predicted FDC values with respect to second virtual wafers in the second chamber.

### CROSS-REFERENCE TO RELATED APPLICATIONS

This application is based on and claims priority under 35 U.S.C. § 119 to Korean Patent Application No. 10-2023-0019630, filed on Feb. 14, 2023, in the Korean Intellectual Property Office, and Korean Patent Application No. 10-2023-0069447, filed on May 30, 2023, in the Korean Intellectual Property Office, the disclosures of which are incorporated by reference herein in their entireties.

### BACKGROUND

The present disclosure relates to a semiconductor production system and method, and more particularly, to a system and method for producing semiconductors using the concept of a world model.

In semiconductor manufacturing processes, process parameters may be measured using sensors of semiconductor production apparatuses with respect to wafers that are actually being processed. Semiconductor processes may be modeled using such process parameter values, and data on results of processes may be predicted or acquired. However, when process parameter values for actual wafers are used for training a semiconductor process model, astronomical investment costs and a long time may be required to improve semiconductor processes through experiments performed on actual wafers.

### SUMMARY

Embodiments of the present disclosure relate a semiconductor production system and method of producing semiconductors based on a model trained using virtual wafers.

According to an aspect of an example embodiment, a semiconductor production system includes: a first chamber that is configured to be set to a first setting value and process wafers; a second chamber that is configured to be set to a second setting value and process the wafers processed in the first chamber; and at least one processor configured to implement a fault detection and classification (FDC) modeling module. The FDC modeling module configured to: train a first FDC machine learning model to generate, based on the first setting value and first FDC values sensed with respect to the wafers that are being processed in the first chamber that is set to the first setting value, first predicted FDC values with respect to first virtual wafers in the first chamber that is set to the first setting value; and train a second FDC machine learning model to generate, based on the second setting value and second FDC values sensed with respect to the wafers that are being processed in the second chamber that is set to the second setting value, second predicted FDC values with respect to second virtual wafers in the second chamber that is set to the second setting value.

According to an aspect of an example embodiment, a semiconductor production system includes: a first chamber configured to process wafers based on a first setting value; a second chamber configured to process, based on a second setting value, the wafers processed in the first chamber; and a neural network processor configured to: train a first fault detection and classification (FDC) machine learning model, while changing the first setting value, to generate first predicted FDC values for first virtual wafers based on first FDC values sensed with respect to the wafers that are being processed in the first chamber; and train a second FDC machine learning model, while changing the second setting value, to generate second predicted FDC values for second virtual wafers based on second FDC values sensed with respect to the wafers that are being processed in the second chamber.

According to an aspect of an example embodiment, a semiconductor production system includes: setting a first chamber to a first setting value; obtaining first fault detection and classification (FDC) values sensed with respect to a first plurality of wafers that are being processed in the first chamber; training a first FDC machine learning model to generate first predicted FDC values for first virtual wafers in the first chamber based on the first setting value and the first FDC values; setting the first chamber to a second setting value; obtaining second FDC values sensed with respect to a second plurality of wafers that are being processed in the first chamber; and training the first FDC machine learning model to generate second predicted FDC values for second virtual wafers in the first chamber based on the second setting value and the second FDC values.

Aspects of embodiments of the present disclosure are not limited to those mentioned above, and other aspects of embodiments of the present disclosure will be apparently understood by those skilled in the art through the following description.

### BRIEF DESCRIPTION OF THE DRAWINGS

Embodiments will be more clearly understood from the following detailed description taken in conjunction with the accompanying drawings in which:

FIG. 1 is a block diagram illustrating a semiconductor production system according to one or more embodiments;

FIG. 2 is a diagram illustrating a semiconductor production system according to an embodiment;

FIG. 3 is a diagram illustrating fault detection and classification (FDC) data according to an embodiment;

FIG. 4 is a flowchart illustrating a semiconductor production method according to an embodiment;

FIG. 5 is a diagram illustrating a semiconductor production system according to an embodiment;

FIG. 6 is a diagram illustrating a semiconductor production system according to an embodiment;

FIG. 7 is a flowchart illustrating a semiconductor production method according to an embodiment;

FIG. 8 is a flowchart illustrating a semiconductor production method according to an embodiment;

FIG. 9 is a flowchart illustrating a semiconductor production method according to an embodiment;

FIG. 10 is a flowchart illustrating a semiconductor production method according to an embodiment;

FIG. 11 is a flowchart illustrating a semiconductor production method according to an embodiment; and

FIG. 12 is a block diagram illustrating a computer system according to one or more embodiments.

### DETAILED DESCRIPTION

Hereinafter, non-limiting example embodiments of the present disclosure will be described with reference to the accompanying drawings.

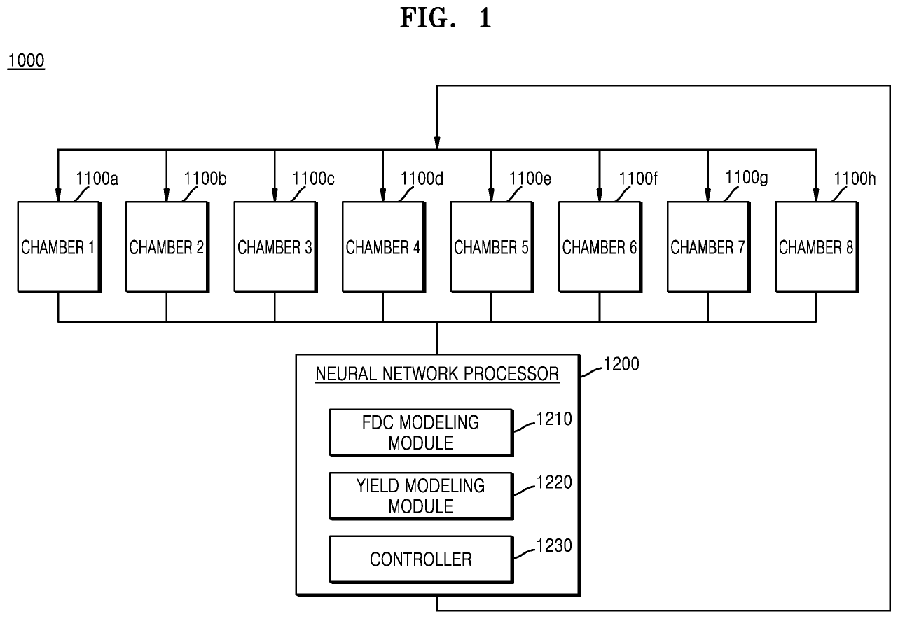

FIG. 1 is a block diagram illustrating a semiconductor production system 1000 according to one or more embodiments.

Referring to FIG. 1, according to the embodiments, the semiconductor production system 1000 may include first to eighth chambers 1100a to 1100h and a neural network processor 1200. The first to eighth chambers 1100a to 1100h may also be referred to as first to eighth semiconductor production apparatuses, respectively. Although FIG. 1 illustrates that the semiconductor production system 1000 includes eight semiconductor production apparatuses, that is, the first to eighth chambers 1100a to 1100h, the number of semiconductor production apparatuses may be any natural number. The first to eighth chambers 1100a to 1100h may be examples of various semiconductor production apparatuses used in semiconductor processes.

In some embodiments, the first chamber 1100a may include an etching apparatus. The first chamber 1100a may be configured to remove at least a portion of a wafer or a layer of material from a wafer. The first chamber 1100a may include at least one selected from the group comprising or consisting of a dry etching apparatus and a wet etching apparatus.

In some embodiments, the second chamber 1100b may include a photolithography apparatus. The second chamber 1100b may be configured to form a photoresist pattern on a wafer. For example, the second chamber 1100b may be configured to form a photoresist layer on a wafer, partially expose the photoresist layer to light, and partially remove the photoresist layer. The second chamber 1100b may include at least one selected from the group comprising or consisting of a photoresist coating apparatus (for example, spin coating apparatus), a light exposure apparatus, and a developing apparatus.

In some embodiments, the third chamber 1100c may include a cleaning apparatus. The third chamber 1100c may be configured to remove residue or contaminants from a wafer or a material layer from a wafer. The third chamber 1100c may include at least one selected from the group comprising or consisting of a wet cleaning apparatus, a dry cleaning apparatus, and a vapor cleaning apparatus.

In some embodiments, the fourth chamber 1100d may include a chemical vapor deposition (CVD) apparatus. The fourth chamber 1100d may be configured to form a material layer on a wafer using a CVD method. The fourth chamber 1100d may include at least one selected from the group comprising or consisting of a thermal CVD device, a plasma CVD device, and an optical CVD device. The semiconductor production system 1000 may further include at least one selected from the group comprising or consisting of a physical vapor deposition (PVD) apparatus, an atomic layer deposition (ALD) apparatus, and an electrical plating apparatus.

In some embodiments, the fifth chamber 1100e may include a chemical physical polish (CMP) apparatus. The fifth chamber 1100e may be configured to planarize a wafer or remove a material layer from a wafer by polishing the wafer or the material layer on the wafer.

In some embodiments, the sixth chamber 1100f may include an ion implant device. The sixth chamber 1100f may be configured to implant ions of a dopant into a wafer or a material layer formed on the wafer. The dopant may include at least one selected from the group comprising or consisting of Group 15 elements and Group 13 elements. The Group 15 elements may include phosphorus (P), arsenic (As), or a combination thereof. The Group 13 elements may include boron (B).

In some embodiments, the seventh chamber 1100g may include a diffusion apparatus. The seventh chamber 1100g may be configured to diffuse dopant ions into a wafer or a material layer formed on the wafer.

In some embodiments, the eighth chamber 1100h may include a metallization apparatus. The eighth chamber 1100h may be configured to form metal wiring on a wafer.

The first to eighth chambers 1100a to 1100h may sequentially process wafers. The first to eighth chambers 1100a to 1100h may each include at least one sensor for measuring fault detection and classification (FDC) data. For example, each of the first to eighth chambers 1100a to 1100h may include at least one selected from the group comprising or consisting of a temperature sensor, a pressure sensor, a flow rate sensor, a humidity sensor, a pH sensor, a position sensor, a power sensor, a voltage sensor, and a current sensor. The FDC data may include process parameters such as temperature, pressure, flow rate, pH, humidity, illuminance, time, voltage, power, and current.

The FDC data may include process parameter values sensed with respect to wafers that are processed in the first to eighth chambers 1100a to 1100h. The FDC data may be referred to as FDC values. The FDC data may include temperature values, pressure values, pH values, or the like that are sensed with respect to wafers that are being processed. The FDC data will be further described later.

Each of the first to eighth chambers 1100a to 1100h may be set to a setting value. For example, the first chamber 1100a may be set to a first setting value, and the first chamber 1100a may then be set to a second setting value. Alternatively, the second chamber 1100b may be set to a second setting value. For example, the first chamber 1100a may be set to treat or process wafers at 22° C. However, unlike the setting of the first chamber 1100a, when a wafer is actually processed, a temperature value sensed with respect to the wafer may be different from the setting value of 22° C. In other words, setting values to which chambers are set may be different from FDC values sensed with respect to wafers. When wafers are processed, FDC values sensed with respect to the wafers may be different from each other depending on a relation between process parameters, the number of wafers, the process order of wafers, a relation between chambers, or the like. The numerical values described above are only examples for ease of description, and embodiments are not limited thereto.

The neural network processor 1200 may include an FDC modeling module 1210, a yield modeling module 1220, and a controller 1230.

The neural network processor 1200 may obtain FDC values sensed with respect to wafers that are being processed in the first to eighth chambers 1100a to 1100h, and setting values for setting the first to eighth chambers 1100a to 1100h. The neural network processor 1200 may generate, based on the obtained FDC values and setting values, predicted FDC values that are FDC values to be sensed with respect to virtual wafers expected to be processed in the first to eighth chambers 1100a to 1100h.

For example, the neural network processor 1200 may build a machine learning model for each of the first to eighth chambers 1100a to 1100h. For example, the FDC modeling module 1210 may train FDC machine learning models to generate, based on FDC values sensed in each of the first to eighth chambers 1100a to 1100h and setting values of the chambers, predicted FDC values to be sensed with respect to virtual wafers expected to be processed in the first to eighth chambers 1100a to 1100h. For example, the FDC modeling module 1210 may train a first FDC machine learning model to generate first predicted FDC values for virtual wafers in the first chamber 1100a based on FDC values sensed with respect to a plurality of wafers that are being processed in the first chamber 1100a and the first setting value for the first chamber 1100a. In addition, the FDC modeling module 1210 may train a second FDC machine learning model to generate second predicted FDC values for virtual wafers in the second chamber 1100b based on FDC values sensed with respect to a plurality of wafers processed in the second chamber 1100b and the second setting value for the second chamber 1100b. The FDC modeling module 1210 may train FDC machine learning models respectively for the third to eighth chambers 1100c to 1100h. A linear regression algorithm, a support vector machine algorithm, a decision tree algorithm, a random forest algorithm, an XGBoost algorithm, a least absolute shrinkage and selection operator (LASSO) algorithm, a transformer algorithm, or a gradient boost algorithm may be used as an algorithm for training the FDC machine learning models. Methods of operating the FDC modeling module 1210 will be further described later.

In addition, the neural network processor 1200 may predict semiconductor yields for virtual wafers based on FDC values predicted for virtual wafers. For example, the yield modeling module 1220 may train a yield machine learning model to generate semiconductor yields predicted for virtual wafers based on the first predicted FDC values and the second predicted FDC values. As data for training the yield machine learning model, FDC values measured from actual wafers or FDC values predicted for virtual wafers may be used. Operations of the yield modeling module 1220 according to the embodiments are not limited thereto. For example, the yield machine learning model may be trained to generate predicted semiconductor yields based on FDC values predicted for virtual wafers in the third to eighth chambers 1100c to 1100h. Methods of operating the yield modeling module 1220 will be further described later.

In addition, the neural network processor 1200 may control, change, or adjust at least one of the first to eighth chambers 1100a to 1100h based on a generated machine learning model. For example, the neural network processor 1200 may control, change, or adjust at least one of the first to eighth chambers 1100a to 1100h to achieve desired process result values. For example, after finding process parameters that most affect semiconductor yields, the neural network processor 1200 may control, change, or adjust at least one of the first to eighth chambers 1100a to 1100h (e.g., first to eight semiconductor production apparatuses) to change a corresponding process parameter and thus improve semiconductor yields. For example, the neural network processor 1200 may adjust setting values of the first to eighth chambers 1100a to 1100h. For example, the controller 1230 may adjust setting values of the first to eighth chambers 1100a to 1100h based on a predicted semiconductor yield. The controller 1230 may set the first to eighth chambers 1100a to 1100h to setting values corresponding to the highest semiconductor yield among semiconductor yields predicted with respect to virtual wafers.

The neural network processor 1200 may be configured to generate tensor data from raw data including FDC data obtained from sensors of the first to eighth chambers 1100a to 1100h, and may model a semiconductor process based on the tensor data.

According to embodiments of the present disclosure, the neural network processor 1200 may include at least one process and memory storing computer instructions. The computer instructions, when executed by the at least one processor, may be configured to cause the neural network processor 1200 to perform its functions (e.g., implement the FDC modeling module 1210, the yield modeling module 1220, and/or the controller 1230).

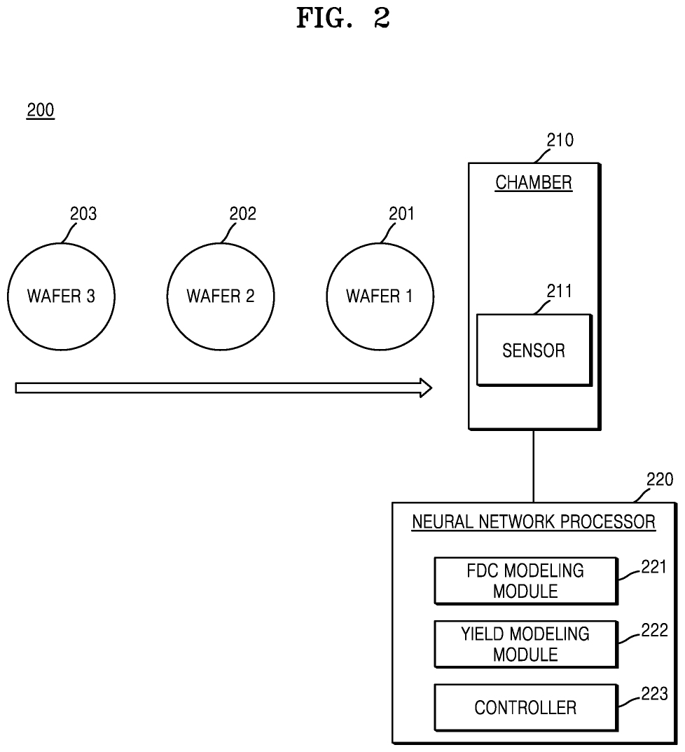

FIG. 2 is a diagram illustrating a semiconductor production system 200 according to an embodiment.

Referring to FIG. 2, the semiconductor production system 200 of the embodiment may include a chamber 210 and a neural network processor 220.

The chamber 210 may correspond to any one of the first to eighth chambers 1100a to 1100h described with reference to FIG. 1. In addition, the semiconductor production system 200 may include a plurality of chambers.

The chamber 210 may be configured to process a plurality of wafers. For example, the chamber 210 may be configured to sequentially process first, second, and third wafers 201, 202, and 203. In addition, the chamber 210 may be configured to process wafers based on setting values. For example, the chamber 210 may be first set to a first setting value, and wafers may be processed based on the first setting value.

The chamber 210 may include a sensor 211. The chamber 210 may obtain FDC values that are sensed using the sensor 211 from the first, second, and third wafers 201, 202, and 203 that are being processed. For example, the chamber 210 may obtain an FDC value sensed with respect to the first wafer 201 that is being processed, an FDC value sensed with respect to the second wafer 202 that is being processed, and an FDC value sensed with respect to the third wafer 203 that is being processed. Even when the first, second, and third wafers 201, 202, and 203 are processed in the chamber 210 that is set to the first setting value to the first setting value, the FDC values sensed with respect to the first, second, and third wafers 201, 202, and 203 may be different from each other, for example, depending on the processing order of the first, second, and third wafers 201, 202, and 203 in the chamber 210. In addition, the first setting value may be different from the FDC values sensed using the sensor 211, and thus, the first setting value and the FDC values may be different from each other.

The neural network processor 220 may include an FDC modeling module 221, a yield modeling module 222, and a controller 223. The neural network processor 220, the FDC modeling module 221, the yield modeling module 222, and the controller 223 may respectively correspond to the neural network processor 1200, the FDC modeling module 1210, the yield modeling module 1220, and the controller 1230 that are described with reference to FIG. 1.

The FDC modeling module 221 may train an FDC machine learning model to generate first predicted FDC values for virtual wafers in the chamber 210 based on the first setting value and the FDC values. For example, assuming that there is a virtual wafer that is expected to be processed after the third wafer 203 is processed, the FDC modeling module 221 may train the FDC machine learning model to generate an FDC value that is predicted to be sensed using the sensor 211 when the virtual wafer is processed. Therefore, the neural network processor 220 may generate predicted FDC values for virtual wafers using the trained FDC machine learning model.

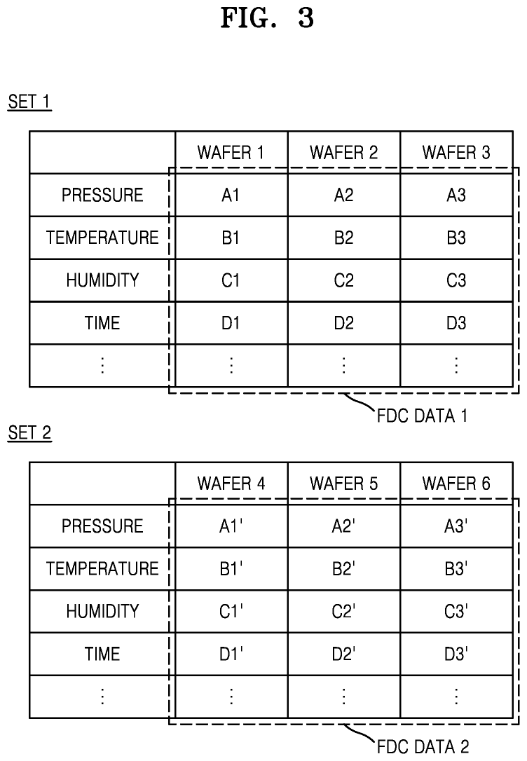

FIG. 3 is a diagram illustrating FDC data according to an embodiment. The following description is given with reference to FIGS. 2 and 3 together.

Referring to FIGS. 2 and 3, the chamber 210 may be set (SET 1) to a first setting value and may be set (SET 2) to a second setting value. The controller 223 may change setting values of the chamber 210.

The chamber 210 may be configured to process the first, second, and third wafers 201, 202, and 203 when the first setting (SET 1) is established. In addition, the chamber 210 may be configured to process fourth to sixth wafers when the second setting (SET 2) is established.

For the first, second, and third wafers 201, 202, and 203 processed in the chamber 210 set to the first setting (SET 1), a first piece of FDC data (FDC DATA 1) may be sensed. In addition, for the fourth to sixth wafers processed in the chamber 210 set to the second setting (SET 2), a second piece of FDC data (FDC DATA 2) may be sensed. The first piece of FDC data and the second piece of FDC data may include information about process parameters such as pressure, temperature, humidity, time, or the like. Because the first piece of FDC data and the second piece of FDC data are sensed with respect to wafers processed in the chamber 210 set to different setting values, the first piece of FDC data and the second piece of FDC data may include different values.

The FDC modeling module 221 may train the FDC machine learning model to generate, based on the first setting value and the first FDC values, first predicted FDC values for virtual wafers in the chamber 210 that is set to the first setting value.

In addition, the FDC modeling module 221 may train the FDC machine learning model to generate, based on the second setting value and the second FDC values, second predicted FDC values for virtual wafers in the chamber 210 that is set to the second setting.

In this case, the FDC modeling module 221 may train the FDC machine learning model by considering a relation between process parameters included in the first FDC values and the second FDC values.

In addition, the neural network processor 220 may obtain FDC values by changing setting values for the chamber 210 using the controller 223 and may train the FDC machine learning model based on the FDC values and the changed setting values. For example, the neural network processor 220 may train the FDC machine learning model while changing the setting values of the chamber 210 to find a setting value corresponding to a high semiconductor yield.

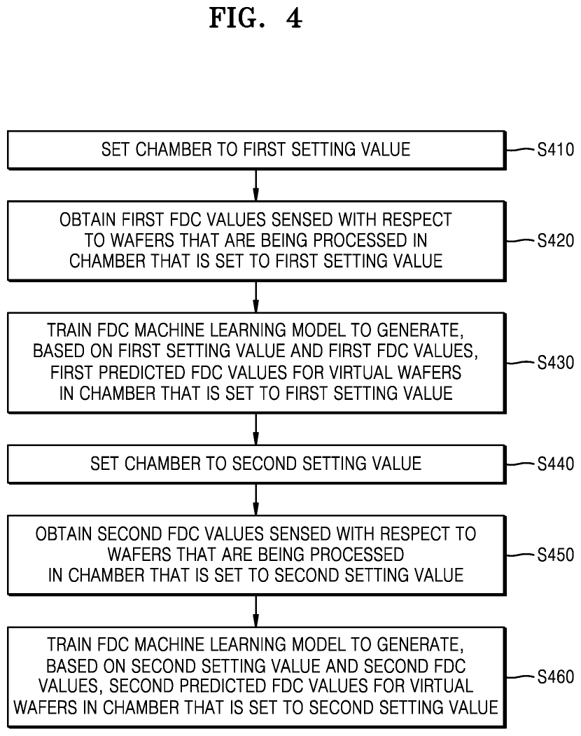

FIG. 4 is a flowchart illustrating a semiconductor production method according to an embodiment.

Referring to FIG. 4, in operation S410 of the semiconductor production method of the embodiment, a chamber may be set to a first setting value.

Furthermore, operation S420 of the semiconductor production method is performed to obtain first FDC values sensed with respect to a plurality of wafers that are being processed in the chamber, which is set to the first setting value. Here, the first FDC values may be data including FDC values each sensed with respect to each of a plurality of wafers. For example, assuming that first, second, and third wafers are processed in the chamber that is set to the first setting value, the first FDC values may include all FDC values sensed with respect to each of the first, second, and third wafers. The first FDC values may include information about temperature, pressure, flow rate, pH, humidity, illuminance, time, voltage, power, current, or the like.

Furthermore, in operation S430 of the semiconductor production method, an FDC machine learning model may be trained to generate, based on the first setting value and the first FDC values, first predicted FDC values for virtual wafers in the chamber that is set to the first setting value. For example, according to the semiconductor production method, the FDC machine learning model may be trained to predict, based on the first FDC values and the first setting value for the first, second, and third wafers processed in the first chamber, an FDC value to be sensed with respect to a fourth wafer that is a virtual wafer expected to be processed in the chamber that is set to the first setting value. In addition, according to the semiconductor production method, after the fourth wafer is processed, an FDC value to be sensed with respect to a fifth virtual wafer expected to be processed in the chamber that is set to the first setting value may be predicted using the trained FDC machine learning model and the FDC value predicted for the fourth virtual wafer. The semiconductor production method may generate, using the trained FDC machine learning model, FDC values predicted to be measured with respect to one or more wafers expected to be processed after the fifth virtual wafer is processed. The FDC values predicted for the fourth virtual wafer and the fifth virtual wafer in the chamber that is set to the first setting value may be referred to as first predicted FDC values.

Furthermore, in operation S440 of the semiconductor production method, the chamber may be set to a second setting value.

Furthermore, in operation S450 of the semiconductor production method, second FDC values sensed with respect to a plurality of wafers processed in the chamber that is set to the second setting value may be obtained. Here, like the first FDC values, the second FDC values may be data including FDC values each sensed with respect to each of the plurality of wafers. For example, assuming that sixth to eighth wafers are processed in the chamber that is set to the second setting value, the second FDC values may include all FDC values each sensed with respect to each of the sixth to eighth wafers. The second FDC values may include information about temperature, pressure, flow rate, pH, humidity, illuminance, time, voltage, power, current, or the like.

Furthermore, in operation S460 of the semiconductor production method, the FDC machine learning model may be trained to generate, based on the second setting value and the second FDC values, second predicted FDC values for virtual wafers in the chamber that is set to the second setting value. For example, according to the semiconductor production method, the FDC machine learning model may be trained to predict, based on the second FDC values and the second setting value for the sixth to eighth wafers processed in the chamber that is set to the second setting value, an FDC value to be sensed with respect to a ninth wafer that is a virtual wafer expected to be processed in the chamber that is set to the second setting value. In addition, according to the semiconductor production method, after the ninth wafer is processed, an FDC value to be sensed with respect to a virtual tenth wafer to be processed in the chamber that is set to the second setting value may be predicted using the trained FDC machine learning model and the FDC value predicted for the virtual ninth wafer. The semiconductor production method may generate, using the trained FDC machine learning model, FDC values predicted to be measured for one or more wafers expected to be processed after the virtual tenth wafer is processed. FDC values predicted for the virtual ninth wafer and the virtual tenth wafer in the chamber that is set to the second setting value may be referred to as second predicted FDC values.

In conclusion, a neural network processor may acquire FDC values by changing setting values for the chamber using a controller and may train an FDC machine learning model based on the setting values and the FDC values. The neural network processor may train the FDC machine learning model while changing the setting values for the chamber, to find a setting value corresponding to a high semiconductor yield.

The neural network processor may predict a semiconductor yield of the chamber based on the first predicted FDC values or the second predicted FDC values. The neural network processor may increase semiconductor yields by controlling chambers based on predicted semiconductor yields. For example, when the neural network processor determines that semiconductor yields are affected because a temperature value of first predicted FDC values is lower than a critical temperature value set to reduce defects, the neural network process may control semiconductor production apparatuses to raise the temperature value related to semiconductor manufacture and thus increase semiconductor yields. Methods of operating the neural network processor will be further described later.

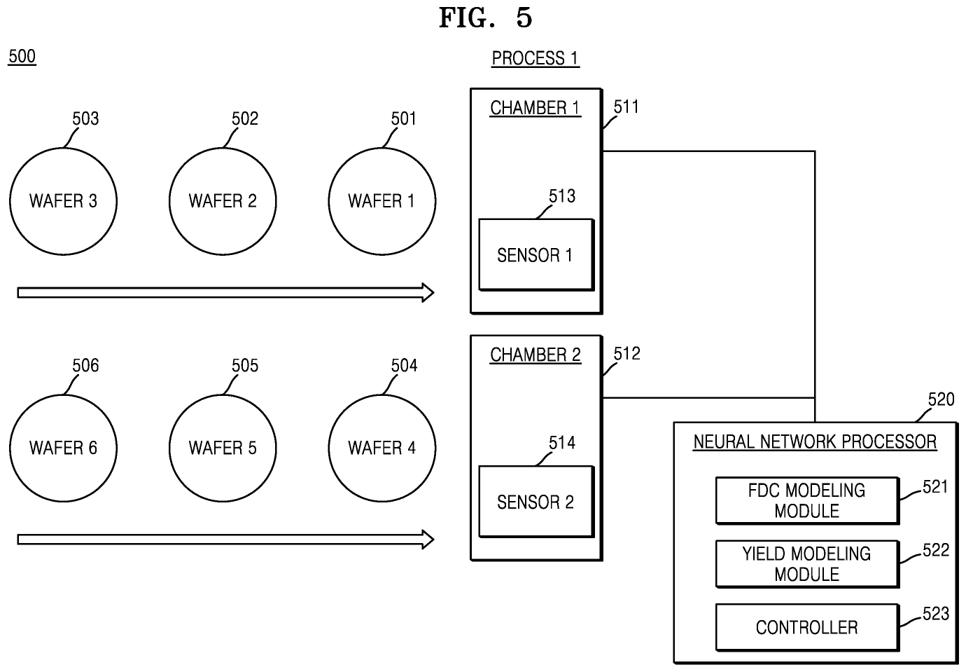

FIG. 5 is a diagram illustrating a semiconductor production system 500 according to an embodiment.

Referring to FIG. 5, the semiconductor production system 500 of the embodiment may include a first chamber 511, a second chamber 512, and a neural network processor 520.

The first chamber 511 and the second chamber 512 may perform the same process on wafers. In other words, the semiconductor production system 500 may include a plurality of chambers configured to perform the same process. For example, each of the first chamber 511 and the second chamber 512 may include an etching apparatus but is not limited thereto. Each of the first chamber 511 and the second chamber 512 may correspond to any one of the first to eighth chambers 1100a to 1100h described with reference to FIG. 1.

The first chamber 511 may be set to a first setting value. The first chamber 511 that is set to the first setting value may process a first wafer 501, a second wafer 502, and a third wafer 503. The first chamber 511 may obtain first FDC values sensed with respect to the first wafer 501, the second wafer 502, and the third wafer 503 by using a first sensor 513 included in the first chamber 511 that is set to the first setting value.

The second chamber 512 may also be set to the first setting value. The second chamber 512 that is set to the first setting value may process a fourth wafer 504, a fifth wafer 505, and a sixth wafer 506. The second chamber 512 may obtain second FDC values sensed with respect to the fourth wafer 504, the fifth wafer 505, and the sixth wafer 506 by using a second sensor 514 included in the second chamber 512 that is set to the first setting value.

Even when the first chamber 511 and the second chamber 512 are configured to perform the same process and are identically set, the first FDC values and the second FDC values may be different from each other due to dispersion or the like.

Unlike the first chamber 511, the second chamber 512 may be set to a second setting value. The second chamber 512 that is set to the second setting value may process the fourth wafer 504, the fifth wafer 505, and the sixth wafer 506. The second chamber 512 may obtain third FDC values sensed with respect to the fourth wafer 504, the fifth wafer 505, and the sixth wafer 506 by using the second sensor 514 included in the second chamber 512.

Even when the first chamber 511 and the second chamber 512 are configured to perform the same process, the first chamber 511 and the second chamber 512 may be differently set. Therefore, the first FDC values and the third FDC values may be different from each other.

The neural network processor 520 may include an FDC modeling module 521, a yield modeling module 522, and a controller 523. The neural network processor 520, the FDC modeling module 521, the yield modeling module 522, and the controller 523 may respectively correspond to the neural network processor 1200, the FDC modeling module 1210, the yield modeling module 1220, and the controller 1230 that are described with reference to FIG. 1.

The FDC modeling module 521 may train an FDC machine learning model to generate, based on the first setting value and the first FDC values, first predicted FDC values for virtual wafers in the first chamber 511 that is set to the first setting value.

In addition, the FDC modeling module 521 may train the FDC machine learning model to generate, based on the first setting value and the second FDC values, second predicted FDC values for virtual wafers in the second chamber 512 that is set to the first setting value.

In addition, the FDC modeling module 521 may train the FDC machine learning model to generate, based on the second setting value and the third FDC values, second predicted FDC values for virtual wafers in the second chamber 512 that is set to the second setting value.

As described above, the semiconductor production system 500 of the embodiment may build a machine learning model for chambers configured to perform the same process.

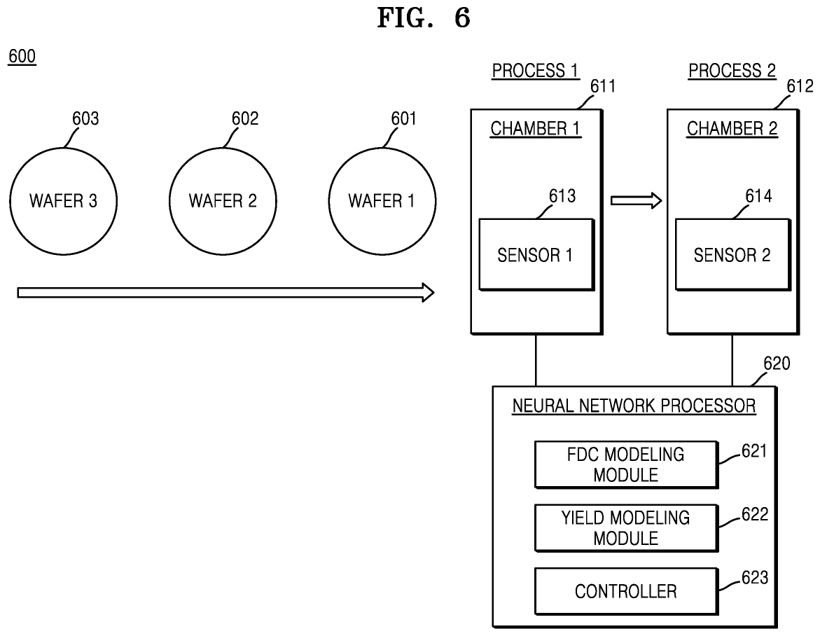

FIG. 6 is a diagram illustrating a semiconductor production system 600 according to an embodiment.

Referring to FIG. 6, the semiconductor production system 600 of the embodiment may include a first chamber 611, a second chamber 612, and a neural network processor 620. The first chamber 611 may include a first sensor 613, and the second chamber 612 may include a second sensor 614. In addition, the neural network processor 620 may include an FDC modeling module 621, a yield modeling module 622, and a controller 623.

The first chamber 611 may be configured to process wafers. For example, the first chamber 611 may be configured to sequentially process first, second, and third wafers 601, 602, and 603.

The second chamber 612 may be configured to process wafers processed in the first chamber 611. Therefore, the first chamber 611 and the second chamber 612 may perform different processes on wafers.

For ease of description, it may be assumed that wafers are completely processed only through a first process in the first chamber 611 and a second process in the second chamber 612. However, the semiconductor production system 600 of the embodiment is not limited thereto. In addition, the semiconductor production system 600 may further include chambers configured to perform the same process as the first chamber 611 or the second chamber 612.

The neural network processor 620 may change a setting value of the first chamber 611 and a setting value of the second chamber 612 and may train a first FDC machine learning model for the first chamber 611 and a second FDC machine learning model for the second chamber 612.

For example, the FDC modeling module 621 may train the first FDC machine learning model to generate first predicted FDC values for virtual wafers in the first chamber 611, based on a first setting value and first FDC values sensed with respect to a plurality of wafers that are being processed in the first chamber 611 that is set to the first setting value.

In addition, the first setting value may be changed by the controller 623. In such a case, the FDC modeling module 621 may train the first FDC machine learning model by reflecting information in new setting values and FDC values sensed under the new setting values. For example, the FDC modeling module may train the first FDC machine learning model to generate, based on a second setting value and second FDC values sensed with respect to a plurality of wafers that are being processed in the first chamber 611 that is set to the second setting value, second predicted FDC values for virtual wafers in the first chamber 611 that is set to the second setting value.

In addition, the FDC modeling module may train the second FDC machine learning model to generate, based on a third setting value and third FDC values sensed with respect to a plurality of wafers that are being processed in the second chamber 612 that is set to the third setting value, third predicted FDC values for virtual wafers in the second chamber 612 that is set to the third setting value.

In addition, the third setting value may be changed by the controller 623. In such a case, the FDC modeling module 621 may train the second FDC machine learning model by reflecting information in new setting values and FDC values sensed under the new setting values. For example, the FDC modeling module may train the second FDC machine learning model to generate, based on a fourth setting value and fourth FDC values sensed with respect to a plurality of wafers that are being processed in the second chamber 612 that is set to the fourth setting value, fourth predicted FDC values for virtual wafers in the second chamber 612 that is set to the fourth setting value.

The yield modeling module 622 may train a yield machine learning model to generate predicted semiconductor yields for virtual wafers based on the first predicted FDC values, the second predicted FDC values, the third predicted FDC values, or the fourth predicted FDC values. Thus, the neural network processor 620 may predict semiconductor yields for virtual wafers.

For example, the neural network processor 620 may generate a first predicted yield for virtual wafers based on first predicted FDC values for the first chamber 611 that is set to the first setting value and the third predicted FDC values for the second chamber 612 that is set to the third setting value.

In addition, the neural network processor 620 may generate a second predicted yield for virtual wafers based on the first predicted FDC values for the first chamber 611 that is set to the first setting value and the fourth predicted FDC values for the second chamber 612 that is set to the fourth setting value.

In addition, the neural network processor 620 may generate a third predicted yield for virtual wafers based on the second predicted FDC values for the first chamber 611 that is set to the second setting value and the third predicted FDC values for the second chamber 612 that is set to the third setting value.

In addition, the neural network processor 620 may generate a fourth predicted yield for virtual wafers based on the second predicted FDC values for the first chamber 611 that is set to the second setting value and the fourth predicted FDC values for the second chamber 612 that is set to the fourth setting value.

The yield modeling module 622 may train the first and second FDC machine learning models by considering a relation between the first chamber 611 and the second chamber 612. For example, the yield modeling module 622 may measure a relation between the first predicted FDC values predicted for the first chamber 611 and the third predicted FDC values predicted for the second chamber 612 and may train the yield machine learning model based on the measurement.

The controller 623 may determine a setting value corresponding to the highest semiconductor yield among the first to fourth predicted yields as an optimal setting value. For example, when the second predicted yield is the highest among the first to fourth predicted yields, the first setting value for the first chamber 611 and the fourth setting value for the second chamber 612 may be determined as optimal setting values.

In addition, the controller 623 may adjust the setting values for the first chamber 611 and the second chamber 612 based on the determined optimal setting values. For example, when the second predicted yield is determined to be the highest yield, the first chamber 611 may be set to the first setting value and the second chamber 612 may be set to the fourth setting value. When actual wafers are processed in the first chamber 611 set to the first setting value and the second chamber 612 set to the fourth setting value, a higher semiconductor yield may be obtained than when actual wafers are processed in the first chamber 611 and the second chamber 612 set to other setting values.

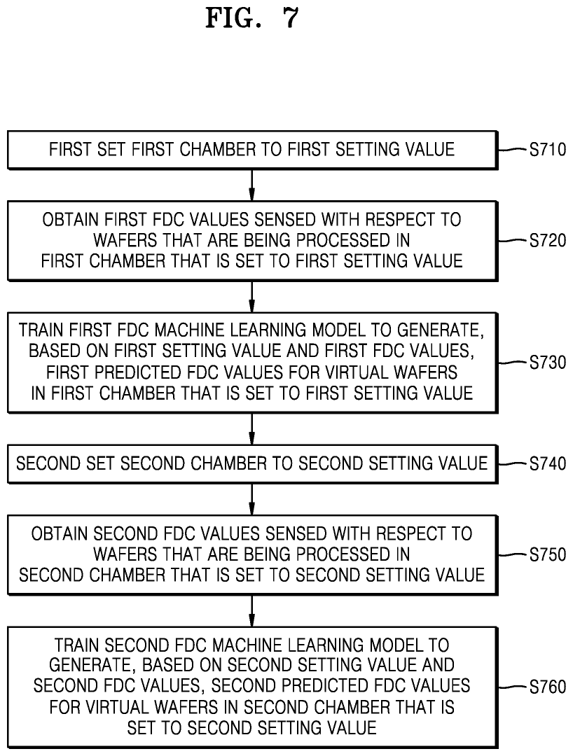

FIG. 7 is a flowchart illustrating a semiconductor production method according to an embodiment.

Referring to FIG. 7, in operation S710 of the semiconductor production method of the embodiment, a first chamber may be set to a first setting value. The first chamber that is set to the first setting value may process wafers introduced into the first chamber based on the first setting value.

In operation S720 of the semiconductor production method, first FDC values sensed with respect to a plurality of wafers that are being processed in the first chamber that is set to the first setting value may be obtained. The first FDC values may include information about temperature, pressure, flow rate, pH, humidity, illuminance, time, voltage, power, current, or the like. Because the first FDC values are sensed with respect to the wafers that are actually being processed, the first FDC values may be different from the first setting value.

In operation S730 of the semiconductor production method, a first FDC machine learning model may be trained to generate, based on the first setting value and the first FDC values, first predicted FDC values for virtual wafers in the first chamber that is set to the first setting value. The virtual wafers may be wafers expected to be processed after actual wafers are processed in the first chamber that is set to the first setting value. The semiconductor production method may use, as an algorithm for training machine learning models, a linear regression algorithm, a support vector machine algorithm, a decision tree algorithm, a random forest algorithm, an XGBoost algorithm, a LASSO algorithm, a transformer algorithm, a gradient boost algorithm, or the like.

In operation S740 of the semiconductor production method, a second chamber may be second set to a second setting value. The second chamber that is set to the second setting value may process wafers introduced into the second chamber based on the second setting value.

In operation S750 of the semiconductor production method, second FDC values sensed with respect to a plurality of wafers that are being processed in the second chamber that is set to the second setting value may be obtained. Because the second FDC values are sensed with respect to wafers that are actually being processed, the second FDC values may be different from the second setting value.

In operation S760 of the semiconductor production method, a second FDC machine learning model may be trained to generate, based on the second setting value and the second FDC values, second predicted FD values for virtual wafers in the second chamber that is set to the second setting value. Here, the virtual wafers may be wafers expected to be processed after actual wafers are processed in the second chamber that is set to the second setting value.

The second chamber may be configured to process wafers processed in the first chamber. In other words, the second chamber may perform a process that is different from a process performed by the first chamber. Therefore, the first chamber and the second chamber may respectively build FDC machine learning models that are different from each other.

According to embodiments of the present disclosure, the semiconductor production method may obtain FDC values sensed with respect to wafers while changing the first setting value for the first chamber and may train the first FDC machine learning model to generate changed predicted FDC values. In other words, the semiconductor production method may train the first FDC machine learning model to generate predicted FDC values with respect the first chamber for various setting values.

In addition, the semiconductor production method may obtain FDC values sensed with respect to wafers while changing the second setting value for the second chamber and may train the second FDC machine learning model to generate changed predicted FDC values. In other words, the semiconductor production method may train the second FDC machine learning model to generate predicted FDC values with respect to the second chamber for various setting values.

For ease of description, the semiconductor production method of the embodiment has been described with respect to the first chamber and the second chamber. However, the semiconductor production method of the embodiment may further involve at least one chamber in addition to the first chamber and the second chamber. In addition, the semiconductor production method may train a machine learning model to generate predicted FDC values for the at least one chamber as well.

The semiconductor production method may obtain predicted FDC values based on virtual wafers, and thus, time and cost for developing semiconductors may be reduced. In addition, according to the semiconductor production method, semiconductors may be developed based on information on virtual wafers and semiconductor production yields may be improved.

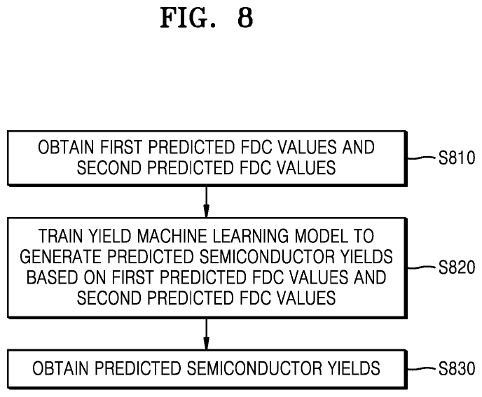

FIG. 8 is a flowchart illustrating a semiconductor production method according to an embodiment.

Referring to FIG. 8, in operation S810 of the semiconductor production method of the embodiment, first predicted FDC values and second predicted FDC values may be obtained. For example, the semiconductor production method may obtain the first predicted FDC values generated in operation S730 described with reference to FIG. 7 and the second predicted FDC values generated in operation S760 described with reference to FIG. 7.

In operation S820 of the semiconductor production method, a yield machine learning model may be trained to generate predicted semiconductor yields based on the first predicted FDC values and the second predicted FDC values. In other words, the semiconductor production method may predict, using the yield machine learning model, semiconductor yields of virtual wafers based on the first and second predicted FDC values regarding the virtual wafers.

In operation S830 of the semiconductor production method, the predicted semiconductor yields may be obtained. Because the predicted semiconductor yields are generated based on predicted FDC values for virtual wafers, the semiconductor production method of the embodiment may reduce time and cost for developing semiconductors. In addition, the semiconductor production method may be used to develop semiconductors and improve semiconductor yields based on information about virtual wafers.

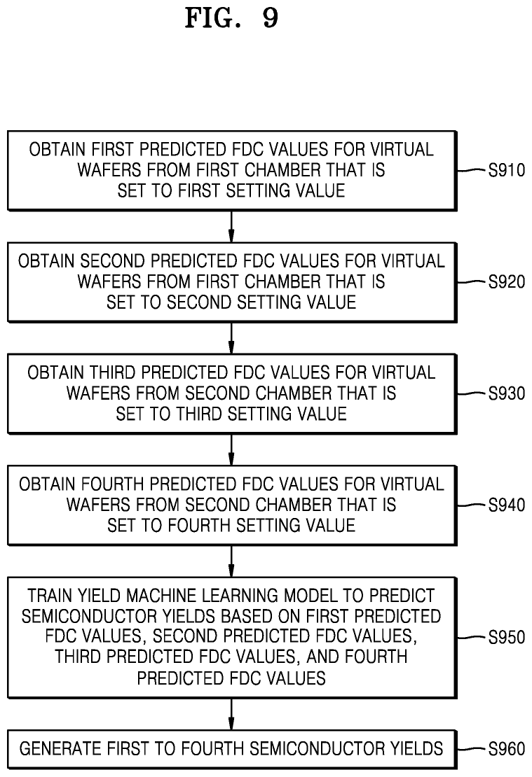

FIG. 9 is a flowchart illustrating a semiconductor production method according to an embodiment.

A semiconductor production system according to an embodiment may produce semiconductors by processing wafers using a plurality of chambers. Hereinafter, it is assumed that wafers are processed using a first chamber and a second chamber. In other embodiments, however, semiconductor production systems may each include three or more chambers.

Each of the first chamber and the second chamber may be set to at least one setting value. For example, the first chamber may be set to one setting value and the second chamber may be set to any one of three setting values. Hereinafter, it is assumed that the first chamber is set to two setting values and the second chamber is also set to two setting values. However, the semiconductor production system of the embodiment is not limited thereto.

Referring to FIG. 9, in operation S910 of the semiconductor production method of the embodiment, first predicted FDC values for virtual wafers are obtained from the first chamber that is set to a first setting value. For example, the semiconductor production method may obtain, through a first FDC machine learning model, the first predicted FDC values based on the first setting value and first FDC values sensed with respect to a plurality of wafers that are being processed in the first chamber that is set to the first setting value.

In operation S920 of the semiconductor production method, second predicted FDC values for virtual wafers may be obtained from the first chamber that is set to a second setting value. For example, the semiconductor production method may obtain, through the first FDC machine learning model, the second predicted FDC values based on the second setting value and second FDC values sensed with respect to a plurality of wafers that are being processed in the first chamber that is set to the second setting value.

In operation S930 of the semiconductor production method, third predicted FDC values for virtual wafers may be obtained from the second chamber that is set to a third setting value. For example, the semiconductor production method may obtain, through a trained second FDC machine learning model, the second predicted FDC values based on the third setting value and third FDC values sensed with respect to a plurality of wafers that are being processed in the second chamber that is set to the third setting value.

In operation S940 of the semiconductor production method, fourth predicted FDC values for virtual wafers may be obtained from the second chamber that is set to a fourth setting value. For example, the semiconductor production method may obtain, through the trained second FDC machine learning model, the fourth predicted FDC values based on the fourth setting value and fourth FDC values sensed with respect to a plurality of wafers that are being processed in the second chamber that is set to the fourth setting value.

In operation S950 of the semiconductor production method, a yield machine learning model may be trained to predict semiconductor yields based on the first predicted FDC values, the second predicted FDC values, the third predicted FDC values, and the fourth predicted FDC values. In other words, the semiconductor production method may predict semiconductor yields based on predicted FDC values for virtual wafers through a machine learning model. FDC values and yields obtained with respect to actual wafers, FDC values predicted for virtual wafers, or the like may be used to train the yield machine learning model.

In operation S960 of the semiconductor production method, a first predicted yield, a second predicted yield, a third predicted yield, and a fourth predicted yield may be generated. For example, the semiconductor production method may generate: a first predicted yield predicted for wafers processed in the first chamber that is set to the first setting value and the second chamber that is set to the third setting value; a second predicted yield predicted for wafers processed in the first chamber that is set to the first setting value and the second chamber that is set to the fourth setting value; a third predicted yield predicted for wafers processed in the first chamber that is set to the second setting value and the second chamber that is set to the third setting value; and a fourth predicted yield predicted for wafers processed in the first chamber that is set to the second setting value and the second chamber that is set to the fourth setting value.

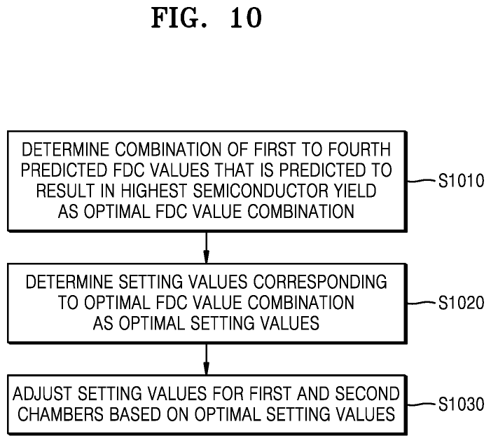

FIG. 10 is a flowchart illustrating a semiconductor production method according to an embodiment.

In operation S1010 of the semiconductor production method of the embodiment, a combination of first to fourth predicted FDC values that is predicted to result in a highest semiconductor yield may be determined as an optimal FDC value combination. Here, the combination of the first predicted FDC values, the second predicted FDC values, the third predicted FDC values, and the fourth predicted FDC values may be understood as a combination of one from among the first predicted FDC values and the second predicted FDC values, and one from among the third FDC values and the fourth FDC values. For example, assuming that the third predicted yield among the first to fourth predicted yields described with reference to FIG. 9 is the highest semiconductor yield, a combination of the second predicted FDC values and the third predicted FDC values that are a basis for generating the third predicted yield may be determined as an optimal FDC value combination.

Furthermore, in operation S1020 of the semiconductor production method, setting values corresponding to the optimal FDC value combination may be determined as optimal setting values. For example, when the optimal FDC value combination is a combination of the second predicted FDC values and the third predicted FDC values, setting values corresponding thereto may be the second setting value for the first chamber and the third setting value for the second chamber. Therefore, the second setting value and the third setting value may be determined as optimal setting values.

Furthermore, in operation S1030 of the semiconductor production method, setting values for the first chamber and the second chamber may be adjusted based on the optimal setting values. For example, when the second setting value and the third setting value are optimal setting values, the semiconductor production method may set the first chamber to the second setting value and the second chamber to the third setting value. In this manner, optimal setting values for chambers may be derived from data on virtual wafers, and actual wafers may be produced after setting the chambers to the optimal setting values. In this case, time and cost for semiconductor production may be reduced and semiconductor yields may be improved.

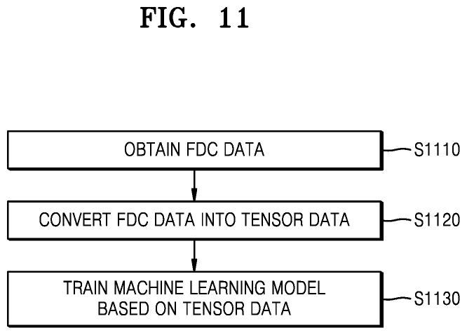

FIG. 11 is a flowchart illustrating a semiconductor production method according to an embodiment.

Referring to FIG. 11, to train a machine learning model, FDC data (e.g., FDC values) may be converted into data suitable for machine learning. The FDC data may include information on process parameter values regarding wafers that have actually been processed, and tensor data may be generated by modifying the FDC data.

For example, according to a semiconductor process modeling method of an embodiment, FDC data may be obtained in operation S1110.

In addition, according to the semiconductor process modeling method, in operation S1120, the FDC data may be converted into tensor data. For example, the semiconductor process modeling method may generate tensor data by considering the FDC data as raw data and modifying the FDC data by tensorization.

Because the tensor data is suitable for machine learning, the semiconductor production method may train a machine learning model based on the tensor data in operation S1130.

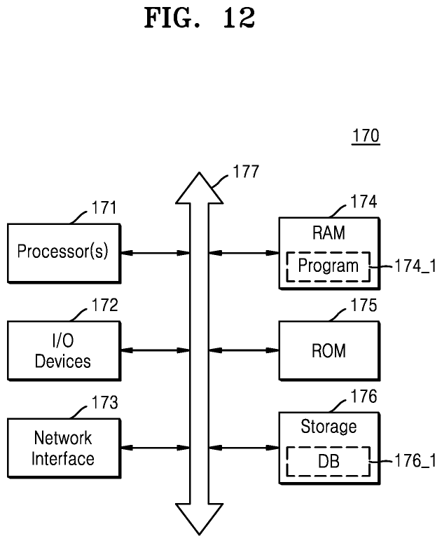

FIG. 12 is a block diagram illustrating a computer system 170 according to embodiments.

The semiconductor production methods described with reference to FIGS. 1 to 11 may be performed using the computer system 170. In some embodiments, the computer system 170 may be referred to as the semiconductor production system 1000 (refer to FIG. 1).

The computer system 170 may include at least one computing device. For example, the computing device may be of a fixed type such as a desktop computer, a workstation, or a server, or may be of a portable type such as a laptop computer, a tablet, or a smartphone.

As shown in FIG. 12, the computer system 170 may include a processor(s) 171, input/output devices 172, a network interface 173, random access memory (RAM) 174, read only memory (ROM) 175, and a storage 176. The processor(s) 171, the input/output devices 172, the network interface 173, the RAM 174, the ROM 175, and the storage 176 may be connected to a bus 177 and may communicate with each other through the bus 177.

The processor(s) 171 may be referred to as a processing unit(s). For example, the processor(s) 171 may include at least one core such as a micro-processor, an application processor (AP), a digital signal processor (DSP), or a graphics processing unit (GPU) that is capable of executing a variety of sets of instructions (for example, Intel Architecture-32 (IA-32)), 64-bit extensions to IA-32, x86-64, PowerPC, scalable processor architecture (SPARC), microprocessor without interlocked pipeline stages (MIPS), Acorn reduced instruction set computer (RISC) machine (ARM), Intel Architecture-62 (IA-64), etc.). For example, the processor(s) 171 may access a memory, that is, the RAM 174 or the ROM 175, through the bus 177 and may execute instructions stored in the RAM 174 or the ROM 175. In addition, the processor(s) 171 may correspond to the neural network processor 1200 described with reference to FIG. 1.

The RAM 174 may store a program 174_1 for modeling a semiconductor process or at least a portion of the program 1741, and the program 1741 may cause the processor(s) 171 to perform a semiconductor production method. That is, the program 174_1 may include a plurality of instructions executable by the processor(s) 171, and the plurality of instructions included in the program 174_1 may cause the processor(s) 171 to perform a semiconductor production method.

The storage 176 may not lose stored data even when power supplied to the computer system 170 is cut off. For example, the storage 176 may include a nonvolatile memory device or may include a storage medium such as magnetic tape, an optical disk, or a magnetic disk. In addition, the storage 176 may be removable from the computer system 170. In an embodiment, the storage 176 may store the program 174_1, and before the program 174_1 is executed by the processor(s) 171, the program 174_1 or at least a portion of the program 174_1 may be loaded from the storage 176 into the RAM 174. Alternatively, the storage 176 may store a file written in a program language, and the program 174_1 or at least a portion of the program 1741 may be generated from the file by a compiler or the like and may be loaded into the RAM 174. In addition, as shown in FIG. 12, the storage 176 may store a database 176_1, and the database 176_1 may include data for semiconductor process modeling, for example, raw data described with reference to FIG. 1.

The storage 176 may store data to be processed by the processor(s) 171 or data processed by the processor(s) 171. That is, the processor(s) 171 may generate data by processing data stored in the storage 176 according to the program 174_1 and may store the generated data. For example, the generated data may include tensor data described with reference to FIG. 1 and predicted process parameter values.

The input/output devices 172 may include an input device such as a keyboard or a pointing device, and an output device such as a display device or a printer. For example, a user may trigger, using the input/output devices 172, the execution of the program 1741 by the processor(s) 171 and may check data resulting from the execution.

The network interface 173 may provide access to a network that is outside the computer system 170. For example, the network may include a plurality of computer systems and a plurality of communication links, and the communication links may include wired links, optical links, wireless links, or links of any other type.

While non-limiting example embodiments of the present disclosure have been particularly shown and described, it will be understood that various changes in form and details may be made therein without departing from the spirit and scope of the present disclosure.

What is claimed is:

1. A semiconductor production system comprising:
a first chamber that is configured to be set to a first setting value and process wafers;
a second chamber that is configured to be set to a second setting value and process the wafers processed in the first chamber; and
at least one processor configured to implement a fault detection and classification (FDC) modeling module, wherein the FDC modeling module is configured to:
train a first FDC machine learning model to generate, based on the first setting value and first FDC values sensed with respect to the wafers that are being processed in the first chamber that is set to the first setting value, first predicted FDC values with respect to first virtual wafers in the first chamber that is set to the first setting value; and
train a second FDC machine learning model to generate, based on the second setting value and second FDC values sensed with respect to the wafers that are being processed in the second chamber that is set to the second setting value, second predicted FDC values with respect to second virtual wafers in the second chamber that is set to the second setting value.

2. The semiconductor production system of claim 1, wherein the at least one processor is further configured to implement a yield modeling module configured to train a yield machine learning model to generate, based on the first predicted FDC values and the second predicted FDC values, predicted semiconductor yields for wafers processed in the first chamber and the second chamber.

3. The semiconductor production system of claim 2, wherein the yield modeling module is further configured to measure a relation between the first predicted FDC values and the second predicted FDC values and train the yield machine learning model based on the relation that is measured.

4. The semiconductor production system of claim 2, wherein the at least one processor is further configured to implement a controller configured to adjust the first setting value and the second setting value to train the first FDC machine learning model and the second FDC machine learning model.

5. The semiconductor production system of claim 4, wherein the controller is further configured to adjust the first setting value and the second setting value to optimal setting values corresponding to a highest semiconductor yield among the predicted semiconductor yields.

6. The semiconductor production system of claim 1, wherein the FDC modeling module is further configured to train the first FDC machine learning model and the second FDC machine learning model by considering a relation between process parameters included in each of the first FDC values and the second FDC values.

7. The semiconductor production system of claim 6, wherein the process parameters comprise at least one from among temperature, pressure, humidity, and pH.

8. The semiconductor production system of claim 1, wherein the FDC modeling module is further configured to train the first FDC machine learning model and the second FDC machine learning model using a least absolute shrinkage and selection operator (LASSO) algorithm or a transformer algorithm.

9. A semiconductor production system comprising:
a first chamber configured to process wafers based on a first setting value;
a second chamber configured to process, based on a second setting value, the wafers processed in the first chamber; and
a neural network processor configured to:
train a first fault detection and classification (FDC) machine learning model, while changing the first setting value, to generate first predicted FDC values for first virtual wafers based on first FDC values sensed with respect to the wafers that are being processed in the first chamber; and
train a second FDC machine learning model, while changing the second setting value, to generate second predicted FDC values for second virtual wafers based on second FDC values sensed with respect to the wafers that are being processed in the second chamber.

10. The semiconductor production system of claim 9, wherein the neural network processor is further configured to train a yield machine learning model to generate, based on the first predicted FDC values and the second predicted FDC values, predicted semiconductor yields for wafers processed in the first chamber and the second chamber.

11. The semiconductor production system of claim 10, wherein the neural network processor is further configured to measure a relation between the first predicted FDC values and the second predicted FDC values and train the yield machine learning model based on the relation that is measured.

12. The semiconductor production system of claim 10, wherein the neural network processor is further configured to:
determine an optimal first setting value of the first chamber and an optimal second setting value of the second chamber that correspond to a highest semiconductor yield among the predicted semiconductor yields, wherein the predicted semiconductor yields are generated based on varying the first setting value and the second setting value; and
set the first setting value of the first chamber and the second setting value of the second chamber to the optimal first setting value and the optimal second setting value, respectively.

13. The semiconductor production system of claim 10, wherein the neural network processor is further configured to train the first FDC machine learning model and the second FDC machine learning model by considering a relation between process parameters included in each of the first FDC values and the second FDC values.

14. The semiconductor production system of claim 13, wherein the process parameters comprise at least one from among temperature, pressure, humidity, and pH.

15. The semiconductor production system of claim 9, wherein the neural network processor is further configured to train the first FDC machine learning model and the second FDC machine learning model using a least absolute shrinkage and selection (LASSO) algorithm or a transformer algorithm.

16. A semiconductor production method comprising:
setting a first chamber to a first setting value;
obtaining first fault detection and classification (FDC) values sensed with respect to a first plurality of wafers that are being processed in the first chamber;
training a first FDC machine learning model to generate first predicted FDC values for first virtual wafers in the first chamber based on the first setting value and the first FDC values;
setting the first chamber to a second setting value;
obtaining second FDC values sensed with respect to a second plurality of wafers that are being processed in the first chamber; and
training the first FDC machine learning model to generate second predicted FDC values for second virtual wafers in the first chamber based on the second setting value and the second FDC values.

17. The semiconductor production method of claim 16, further comprising:
setting a second chamber to a third setting value;
obtaining third FDC values sensed with respect to the first plurality of wafers that are being processed in the second chamber;
training a second FDC machine learning model to generate third predicted FDC values for third virtual wafers in the second chamber based on the third setting value and the third FDC values;
setting the second chamber to a fourth setting value;
obtaining fourth FDC values sensed with respect to the second plurality of wafers that are being processed in the second chamber; and
training the second FDC machine learning model to generate fourth predicted FDC values for fourth virtual wafers in the second chamber based on the fourth setting value and the fourth FDC values,
wherein the second chamber is configured to process the first plurality of wafers and the second plurality of wafers processed in the first chamber.

18. The semiconductor production method of claim 17, further comprising training a yield machine learning model to predict semiconductor yields based on combinations of the first predicted FDC values, the second predicted FDC values, the third predicted FDC values, and the fourth predicted FDC values.

19. The semiconductor production method of claim 18, further comprising:
determining, as an optimal FDC value combination for the first chamber and the second chamber, a combination by which a highest semiconductor yield is predicted among the combinations of the first predicted FDC values, the second predicted FDC values, the third predicted FDC values, and the fourth predicted FDC values; and
setting the first chamber and the second chamber based on setting values corresponding to the optimal FDC value combination.

20. The semiconductor production method of claim 18, wherein the training of the yield machine learning model comprises measuring a relation between the first predicted FDC values and the second predicted FDC values and training the yield machine learning model to predict the semiconductor yields based on the relation.
